(19) United States
(12) Patent Application Publication
(10) Pub. No.: US 2025/0141572 A1
(43) Pub. Date: May 1, 2025

(54) DEVICE, METHOD AND PROGRAM FOR RECORDING RADIOFREQUENCY ACTIVITY OF ARTIFICIAL SATELLITES

(71) Applicant: SAFRAN DATA SYSTEMS, COURTABOEUF CEDEX (FR)

(72) Inventors: Steredenn DAUMONT, MOISSY CRAMAYEL (FR); Yann PICARD, MOISSY CRAMAYEL (FR); Baptiste GUILLOT, MOISSY CRAMAYEL (FR)

(73) Assignee: SAFRAN DATA SYSTEMS, COURTABOEUF CEDEX (FR)

(21) Appl. No.: 18/835,308

(22) PCT Filed: Feb. 2, 2023
(86) PCT No.: PCT/FR2023/050136

§ 371 Date: Aug. 1, 2024

(30) Foreign Application Priority Data
Feb. 2, 2022 (FR) FR2200924

(51) Int. Cl. H04B 17/318; H04B 17/27; H04B 17/29

(52) U.S. Cl. CPC H04B 17/318; H04B 17/27; H04B 17/29

(57) ABSTRACT

The present invention relates to a method and a device for recording radiofrequency activity of artificial satellites orbiting the Earth and emitting electromagnetic signals, characterized in that the device contains an antenna for receiving an acquisition signal, a reception chain, a computer able to compute the power spectral density on at least one frequency sub-band based on the signal, a control device for pointing the line of sight of the antenna at at least one sequence of prescribed orbital positions that are successive and separate from one another.

The invention relates to a device and a method for recording a radiofrequency activity of earth-orbiting artificial satellites, and a computer program for their implementation.

### GENERAL TECHNICAL FIELD

The field of the invention relates to active satellites, in all kinds of orbits.

### STATE OF THE ART

A service for determining the orbits of the geostationary satellites is known, which uses the declarations provided by the operators on the use of the radiofrequency spectrum made by these satellites; it is referred to as “orbital tracking” system.

The known orbital tracking service uses a technique of correlation of the signal emitted by the satellites and acquired by stations remote from each other, typically by a distance of several hundred kilometers. This technique requires transferring large amounts of data to a computing center. A systematic examination of an orbit, such as for example the Clarke belt (geostationary orbit), by this technique, would be limited by the bandwidth of the long-distance communications towards the computing center and would therefore require an unacceptable measurement time and a high cost of communications.

Also, satellites emitting sporadically may not be detected by this method, because the rate of revisiting an orbital position would be too slow (more than a day). In addition, when the orbital tracking by remote stations is failing, it is not obvious to determine what could be the cause of it: change of plan/frequency by the satellite, cessation of satellite communications or other causes.

One objective of the invention is to obtain a device, a method and a computer program for recording a radiofrequency activity coming from earth-orbiting artificial satellites, which make it possible to automatically discover and identify the radiofrequency emissions derived from satellites without prior third-party information, that is to say without considering the declarations provided by the operators and with a short revisit time.

### DISCLOSURE OF THE INVENTION

To this end, a first subject matter of the invention is a method for recording a radiofrequency activity of at least one artificial satellite, which is earth orbiting and which is emitting a radiofrequency signal, characterized in that the method comprises the following steps:
pointing, by an antenna control device, at least one antenna to move an axis of sight of the antenna towards at least one sequence of successive prescribed pointing positions distinct from each other, the antenna being in the form of a reflector, whose external edge delimits a maximum opening diameter, which is less than or equal to 6 meters, and for each prescribed pointing position:
   collecting the radiofrequency signal by the antenna and converting the radiofrequency signal by a radiofrequency chain into a digital signal,
   calculating, by a calculator, at least one recording of raw power spectral densities on at least one receiving frequency sub-band from the digital signal,
   reprocessing the recording of raw power spectral densities into a recording of refined power spectral densities by applying an inverse convolution processing of the radiation pattern of the antenna in the receiving frequency sub-band by the calculator.

Thus, the invention, by the combination of a small antenna and of the inverse convolution makes it possible to detect a greater number of satellites, because the main lobe of the antenna having the small diameter mentioned above is wider, allows covering a greater number of satellites at each antenna pointing position and allows a shorter revisit time (which is the time elapsed to perform all the planned scanning sequences), thus increasing the possibility of detecting a non-permanent emission from a satellite. This makes it possible to increase the measurement pitch from one pointing position to the next pointing position in the sequence and therefore the speed of acquisition of the refined power spectral density, while reducing the cost of the infrastructure.

Thus, the invention makes it possible to detect all the artificial satellites having a radiofrequency activity, whether or not they have been listed. This system is called “spectral mapping”. An examination using only one station at a time on which the device according to the invention is installed can therefore be envisaged. Thanks to the invention, uses not declared by an operator, changes in frequency plan, in orbital position, new station acquisitions or failures regarding earth-orbiting artificial satellites, are listed. The invention makes it possible to reduce the revisit time in order to detect as many events as possible. The invention makes it possible to establish an accurate mapping with a rapid revisit (a few hours at most), while using one or several antennas of limited size and reduced cost. The spectral mapping can therefore be updated frequently, several times a day and every day in order to be capable of identifying with certainty the use changes made by the operator. The invention can create the mapping in the form of a power spectral density map as a function of the pointing position and of the frequency, making it possible to visualize and interpret the origin of the received radiofrequency spectrum, as well as its evolution over time. It is thus possible to detect celestial objects and the use changes (breakdowns, station acquisitions, change of frequency plan) concerning the satellites. The invention can map the use of the frequency spectrum as a function of the orbital position (longitude or anomaly when an orbit is scanned) of all or part of the orbit(s) considered, on one or several receiving frequency sub-bands. The invention can be used to detect satellites on all types of orbits, which therefore comprises the non-geostationary ones.

The invention makes it possible to put the detected satellites into orbital tracking. This makes it possible to dispense with frequency use declarations of the operators and to track these objects, whether or not they have been declared.

According to one embodiment of the invention, the antenna has a maximum opening diameter, which is less than or equal to 4 meters.

According to one embodiment of the invention, the antenna has a maximum opening diameter, which is less than or equal to 2.50 meters.

According to one embodiment of the invention, the antenna has a maximum opening diameter, which is less than or equal to 2.10 meters.

According to one embodiment of the invention, the reprocessing of the recording of raw power spectral densities comprises:
the inverse convolution processing of the radiation pattern of the antenna at a frequency in the receiving frequency sub-band,
the calculation of the impulse response of the inverse convolution from the radiation pattern of the antenna which has been measured beforehand at the same frequency and which has been recorded beforehand in a memory of the calculator.

According to one embodiment of the invention, the inverse convolution is performed for a linear combination of several successive raw power spectral densities for the successive prescribed pointing positions.

According to one embodiment of the invention, the method comprises the pointing of the axis of sight of the antenna following a prescribed scanning trajectory passing through the prescribed pointing positions at consecutive instants.

According to one embodiment of the invention, the prescribed scanning trajectory tracks each prescribed pointing position for a non-zero duration.

According to one embodiment of the invention, the prescribed scanning trajectory connects the prescribed successive pointing positions with a regular speed.

According to one embodiment of the invention, the antenna control device interrupts the displacement of the axis of sight when prescribed pointing positions are located below a predefined minimum elevation.

According to one embodiment of the invention, the successive prescribed pointing positions have the same orbital period.

According to one embodiment of the invention, the prescribed pointing positions of at least one of the sequences of prescribed pointing position move in a determined orbit.

According to one embodiment of the invention, the determined orbit is the Clarke belt of the geostationary satellites.

According to one embodiment of the invention, the axes of sight of the successive prescribed pointing positions are spaced apart by an angle smaller than a width of a main radiation lobe of the antenna, in the time interval where the antenna moves from the prescribed pointing position to the next prescribed pointing position in the sequence.

According to one embodiment of the invention, the calculator reads the raw power spectral density at each prescribed pointing position from the digital signal.

According to one embodiment of the invention, the recording of raw power spectral densities is made by an acquisition of the radiofrequency signal, which is collected by the antenna and which is digitized by the radiofrequency chain according to separate windows of a predefined minimum duration.

According to one embodiment of the invention, to measure the recording of raw power spectral densities at each prescribed pointing position, the calculator for each duration window of the digital signal calculates the Fourier transform then squares its module and divides the whole by the duration of the window.

According to one embodiment of the invention, the average scanning speed of the antenna relative to the tracking speed of the pointing position in the sequence is less than θ/D, where θ is the width of the main radiation lobe of the antenna.

According to one embodiment of the invention, the method comprises the calculation, by the calculator, and a recording, by the calculator, of a mapping constituted by the recordings of refined power spectral densities as a function of the frequency and of the prescribed pointing position.

According to one embodiment of the invention, an image is extracted from the mapping by the calculator, wherein the image arranges side by side the levels of the refined power spectral densities, read successively at the prescribed pointing positions, in the at least one receiving frequency sub-band, the pointing orbital position and the frequency constituting, as desired, the abscissa and ordinate axes of the image.

According to one embodiment of the invention, the level of each refined power spectral density is represented by a pixel value, in particular the color or a brightness level or a gray level.

According to one embodiment of the invention, the calculator searches for peaks on part or on all of the longitudinal level curves of the raw or refined power spectral densities to determine the most probable position of the at least one emitter satellite of the read spectrum.

According to one embodiment of the invention, the probable position(s) of satellites and their associated power spectral density recording are compared by the calculator to the declarations of the operators.

According to one embodiment of the invention, the probable position(s) of associated satellites and possibly all or part of their power spectral density recording are transmitted by the calculator to an orbital tracking system.

A second subject matter of the invention is a device for recording a radiofrequency activity of at least one artificial satellite, which is emitting a radiofrequency signal, characterized in that the device comprises:
at least one receiving antenna pointed along an axis of sight and able to collect the radiofrequency signal, the antenna being in the form of a reflector, whose external edge delimits a maximum opening diameter, which is less than or equal to 6 meters,
an antenna control unit to point the axis of sight of the antenna towards at least one sequence of successive prescribed pointing positions distinct from each other,
a radiofrequency receiving and digital conversion chain, which acquires the radiofrequency signal into a digital signal on at least one receiving frequency sub-band,
a calculator able to calculate, from the digital signal, at least one recording of power spectral densities on the receiving frequency sub-band, and to reprocess the recording of raw power spectral densities into a recording of refined power spectral densities by application of an inverse convolution processing of the radiation pattern of the antenna in the receiving frequency sub-band by the calculator.

According to one embodiment of the invention, the drive device is able to point the axis of sight of the antenna following a prescribed scanning trajectory passing through the prescribed pointing positions at consecutive instants.

According to one embodiment of the invention, the antenna is chosen of just sufficient size to be able to detect the signal from a satellite emitting at the equivalent isotropically radiated power threshold to be detected.

According to one embodiment of the invention, the radiofrequency activity recording device comprises a recording device able to record a mapping constituted by recordings of the power spectral density as a function of the frequency and of the prescribed pointing position.

According to one embodiment of the invention, the recording device is able to record a history of the mapping, that is to say several power spectral density recordings made on different dates concerning the same prescribed pointing position.

According to one embodiment of the invention, the calculator and the recording device are able to constitute at least one differential image between histories of the mapping corresponding to different acquisition dates for the same sequence of prescribed pointing positions.

According to one embodiment of the invention, the spectral density recording is made by acquisition of the radiofrequency signal, which is collected by the antenna and which is digitized by the radiofrequency chain according to separate windows of a predefined minimum duration D.

According to one embodiment of the invention, to measure the power spectral density of the signal at each prescribed pointing position, the calculator for each duration window of the digital signal is configured to calculate the Fourier transform then to square its module and to divide the whole by the duration of the window.

A third subject matter of the invention is a computer program for the implementation of the method for recording a radiofrequency activity of at least one artificial satellite as described above, comprising code instructions for the execution of the pointing, collection, conversion, calculation and reprocessing steps, when the computer program is executed on one or several calculators.

### PRESENTATION OF THE FIGURES

The invention will be better understood upon reading the following description, given solely by way of non-limiting example with reference to the figures below of the appended drawings.

FIG. 1 represents a schematic perspective view of the device for recording the radiofrequency activity of earth-orbiting artificial satellites according to one embodiment of the invention.

FIG. 2 represents a modular overview diagram of the device for recording a radiofrequency activity of earth-orbiting artificial satellites according to one embodiment of the invention.

FIG. 3 represents a flowchart of the method for recording the radiofrequency activity of earth-orbiting artificial satellites according to one embodiment of the invention.

FIG. 4 represents a first example of map image of power spectral densities obtained during a first orbit scan by the device, the method and the computer program for recording a radiofrequency activity of artificial satellites according to one embodiment of the invention.

FIG. 5 represents a second example of map image of power spectral densities obtained by the device, the method and the computer program for recording a radiofrequency activity of artificial satellites according to one embodiment of the invention during a second orbit scan subsequent to the first orbit scan.

FIG. 6 represents a differential map image of power spectral densities, obtained from the first example of map image of FIG. 4 and from the second example of map image of FIG. 5, by the device, the method and the computer program for recording a radiofrequency activity of artificial satellites according to one embodiment of the invention.

FIG. 7 represents a frequency section of a set of Diracs representing satellites, ideally seen as points, to be scanned and acquired by the device, the method and the computer program for recording a radiofrequency activity of artificial satellites according to one embodiment of the invention.

FIG. 8 represents an example of radiation pattern of the antenna of the device, method and computer program for recording a radiofrequency activity of artificial satellites according to one embodiment of the invention.

FIG. 9 represents an example of power spectral density received by the antenna of the device, method and computer program for recording a radiofrequency activity of artificial satellites according to one embodiment of the invention.

FIG. 10 represents an example of map image of a power spectral density obtained by the device, the method and the computer program for recording a radiofrequency activity of artificial satellites according to one embodiment of the invention after an inverse convolution.

FIG. 11 represents an example of map image of power spectral densities obtained by the device, the method and the computer program for recording a radiofrequency activity of artificial satellites according to one embodiment of the invention after an inverse convolution according to FIG. 10 and after searching for the peaks.

FIG. 12 schematically represents a geocentric reference frame, in which parameters of a satellite can be defined.

### DETAILED DESCRIPTION OF THE INVENTION

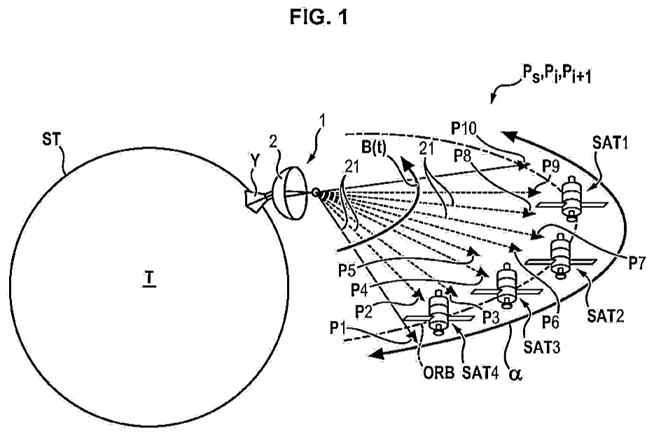

In FIG. 1, the recording device 1 according to the invention can be used to detect a radiofrequency activity of one or several satellites SAT1, SAT2, SAT3, SAT4 (or generally space objects or celestial objects) located on one or several terrestrial orbital positions Ps around the earth T. The recording device 1 is installed in a determined geographical position Y of the surface ST of the globe T. The satellite(s) SAT1, SAT2, SAT3, SAT4 or space objects can emit electromagnetic signals towards the surface ST and towards the recording device 1. In FIG. 1, the orbit ORB of the satellites SAT1, SAT2, SAT3, SAT4 can be any orbit, and for example low earth orbit LEO whose period of revolution is less than 128 minutes, geostationary orbit appearing fixed from the earth T and therefore of period of revolution equal to one sidereal day, or medium earth orbit MEO that is to say between the two. The recording device 1 implements the steps described below of a method for recording a radiofrequency activity of one or several satellites according to the invention.

One or several stations located on the surface ST of the globe T can be provided, the station or each station comprising the recording device 1 according to the invention. The work of each station can be planned, for example centrally in the case of several stations, so that the work of the stations is complementary.

In a non-limiting embodiment, several antennas 2 and devices 1 according to the invention can be distributed over different points of the globe T in order to be able to cover all the orbital positions of interest and all the sub-bands Wₓ of target frequencies.

### Main Parts of the Recording Device

The recording device 1 according to the invention comprises the elements which will be described in more detail below:
An antenna 2,
A radiofrequency receiving and digital conversion chain 20,
A calculator 3,
A device 4 for pointing the antenna 2,
A device 5 for recording a mapping.

### Steps of the Tracking Method

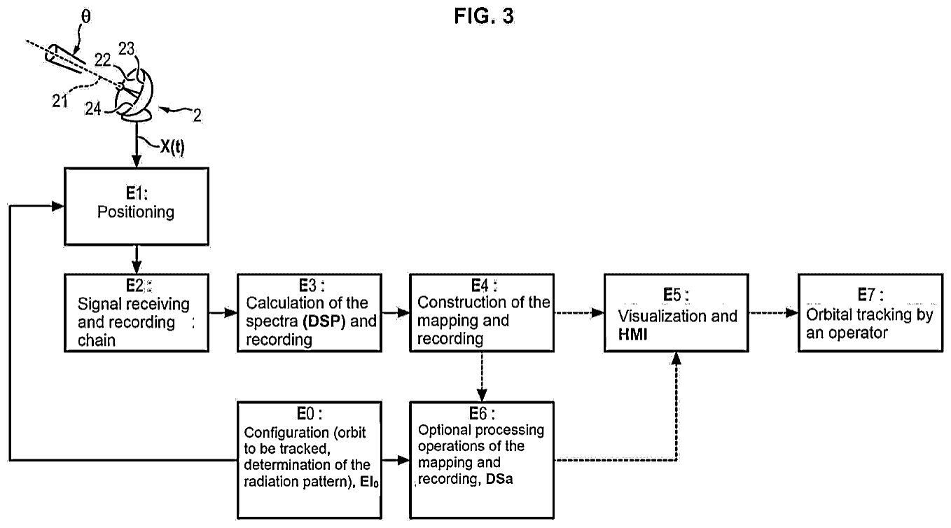

In one preferred embodiment, the steps of the recording method according to the invention follow the description given below. They describe the different operations that contribute to the invention. They actually take place non-sequentially, that is to say several steps take place concurrently. One or several of these steps can be omitted or implemented according to alternatives, with reference to FIG. 3.

### Step E0: Configuration of the Device 1

The user of the recording system must plan the scans and signal acquisitions to be performed. To do so, it configures the device 1 for recording the mapping. The user first configures the specific characteristics of the station. These are useful for executing the subsequent steps:

For the step E1 of pointing the antenna,
the geographical position O of the antenna 2, in longitude and latitude,
the minimum pointing elevation El₀ of the antenna 2,
the maximum pointing speed,
the width θ of the main lobe,
One or several orbits or more generally the sequence(s) of successive orbital positions to be scanned for each recording,
the regular or discreet scanning mode to be implemented, are configured.
   For the step E2 of collecting the signal,
the drive of the radiofrequency chain 20, in particular the equipment gains,
the sub-bands Wₓ read from the spectrum, the frequency plan of the converters, are configured.
   For the step E3 of recording the power spectral density,
the expected frequency resolution,
the averaging to be implemented, are configured.
   For the step E4 of constructing the mapping,
the data structure to be recorded, covering all the orbital positions that are examined,
   is configured.
   For the visualization step E5,
Visualization parameters, modifiable by the user, are configured.
   For the optional step E6 of reprocessing the mapping,:
the radiation pattern of the antenna 2, when carrying out an inverse convolution operation, is configured. The radiation pattern may have been measured beforehand.
   For the optional step E7 of putting into orbital tracking,
the format and destination of the data to be provided to the tracking system are configured.

### Step E1: Positioning/Pointing

The recording device 1 comprises an antenna 2 control unit 4, called ACU, to point satellites whose orbital position Pₛ is pointed at an elevation greater than the minimum elevation El₀ defined in the configuration step E0. The ACU 4 which contains a calculator, controls the motors of the positioner of the antenna 2 so that its axis of sight 21 points towards a pointing position, such as for example those described below. The ACU 4 of a station according to the state of the art which would communicate with a satellite SAT located at this pointing position calculates the evolution as a function of time t of the location S(Pₛ,t) of the pointing position, then the angle of the axis of sight 21 β[OS(Pₛ,t)] which will be noted for the sake of simplification β(Pₛ,t), where O is the geographical location of the station. By convention, the angle of the axis of sight 21 is determined by the azimuth and the elevation of the straight line OS(t), relative to the horizontal plane and to the geographic north. Also, the ACU 4 must first convert the geographical position O of the station into position in the geocentric reference frame for which the orbital parameters of the satellite are given. It is therefore necessary to take into account for this purpose the rotation of the earth on itself and around the sun.

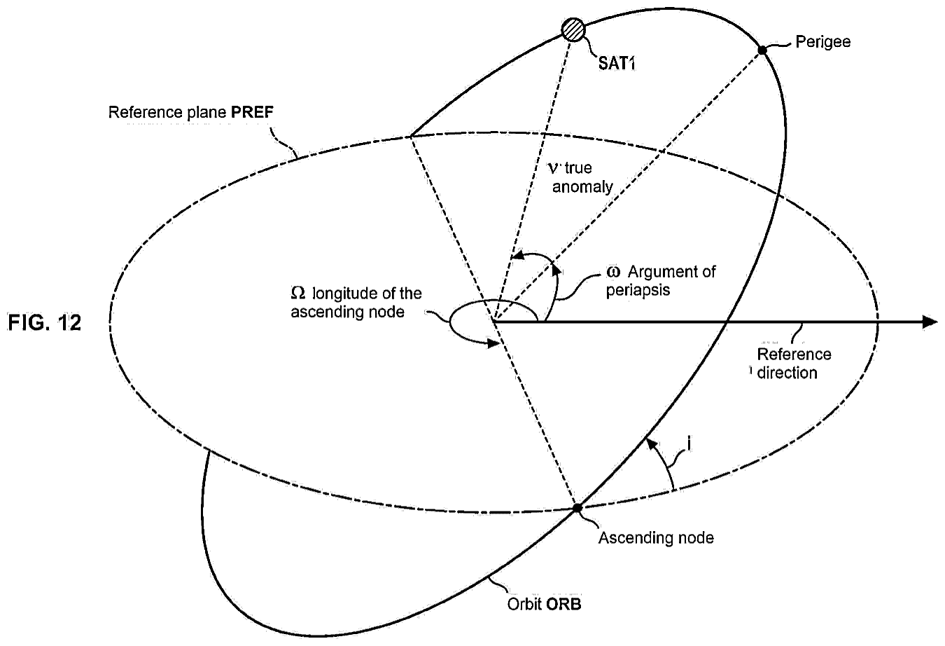

Within the framework of classical mechanics and gravitational attraction by a single revolution star, the orbits obey Kepler's laws. In a geocentric reference frame, as illustrated in FIG. 12, that is to say positioned at the center of the earth and whose axes point fixed stars, each orbit ORB is an ellipse inscribed in an orbital plane whose center of the earth is one of the focuses. An orbital position of a satellite is entirely determined by six parameters. In the most common standardized descriptions, such as TLEs (Two Line Elements), the orbital plane is defined by two parameters (inclination i relative to a reference plane PREF and ascending node). The orientation of the ellipse in the orbital plane is defined by the angle of its perigee (point of the orbit ORB closest to the earth), when the eccentricity indicates the flattening of the ellipse and therefore the ratio between its major axis and its minor axis. The size of the semi-major axis of the ellipse a and the period of revolution Pᵣ are related by the third Kepler's law: Pᵣ²/a³=4π²/GM where M is the mass of the earth and G the universal constant of gravity. The fifth parameter can therefore be chosen indifferently as the period of revolution or the semi-major axis. Conventionally, it is considered in the following that the orbits ORB are described by their period of revolution Pᵣ. Rather than the period of revolution, the TLEs in fact provide the average movement which corresponds to the fractional number of rotations per day, which is equivalent.

These five first parameters make it possible to unequivocally determine an ellipse in space, that is to say the trajectory followed by the satellite which is called the orbit. The last parameter to describe an orbital position is the anomaly that allows knowing at any instant the angular position of the satellite on the ellipse. The anomaly can be defined in several ways: true anomaly v, eccentric anomaly or average anomaly, this choice does not matter for the invention.

The orbital position of a satellite drifts slowly, under the effects of variations of the earth's gravity, of the moon and sun tides, of the general relativity, and of the solar wind. These effects are noticeable over periods of several days. Most often, a satellite is assigned to an orbital position, it maneuvers to stay there. Some satellites are intended to change their orbital position (space monitoring, on-orbit service). The invention makes it possible to identify all these movements.

In the invention, the planning programmed in step E0 provides for moving the axis of sight 21 of the antenna 2 towards a sequence of successive prescribed pointing positions Pᵢ distinct from each other, which are for example P1, P2, P3, P4, P5, P6, P7, P8, P9, P10 in FIG. 1 for i varying for example from 1 to 10. There may be a prescribed pitch between the successive pointing positions. The prescribed pointing positions can be for example prescribed orbital positions P1, P2, P3, P4, P5, P6, P7, P8, P9, P10. The index i successively takes a value ranging from 1 to N, where N is any integer number of pointing positions. During a scan, the positions Pᵢ are actually reached at instants tᵢ which constitute an increasing sequence of dates. These prescribed pointing positions Pᵢ are spatial positions of interest where satellites SAT1, SAT2, SAT3, SAT4 may be located and from which the emitted radio signal is collected to measure its power spectral density. The antenna control unit which drives the antenna 2 according to the invention performs the same operations of calculating the axis of sight 21 as those of an ACU tracking a satellite at the orbital position Pₛ, but it repeats this operation by taking each time the next pointing position in the sequence while an ACU in tracking mode maintains the same orbital position.

The axis of sight 21 must necessarily evolve continuously, also the ACU must interpolate the pointing positions between the instants tᵢ and tᵢ₊₁ to create a continuous scanning curve B(t). Two scanning modes are possible. The first one, called discrete scanning mode, consists in tracking a fixed pointing position then joining the next one as quickly as possible, given the maximum speed at which the positioner can move. In this case, the pointing position stops on Pᵢ at tᵢ and remains there for a certain time before meeting Pᵢ₊₁ as quickly as possible. The second one, called regular scanning mode, consists in gradually varying the characteristics from the target pointing position to the next one. In this case, each pointing parameter gradually evolves from the value of the parameter of the pointing position Pᵢ to that of Pᵢ₊₁ between tᵢ and tᵢ₊₁. By construction, in the two scanning modes, we have for each instant tᵢ: B(tᵢ)=β[OS(Pᵢ, tᵢ)]=β(Pᵢ, tᵢ).

The ACU 4 must check at every instant that the elevation of the axis of sight 21 remains greater than the minimum value El₀ defined in the configuration step E0. For each pointing position, the ACU must determine whether it respects the minimum elevation. During the scanning, as soon as a pointing position causes an axis of sight 21 whose elevation is lower than the minimum elevation El₀, it ignores the pointing position and moves directly to the next one. For each sequence, the scanning curve B(t) traverses an arc portion, whose developed angle is denoted α. The latter will therefore be smaller than the arc whose scan has been planned in step E0, as long as part of this arc is at an elevation lower than the minimum elevation. When the ACU has completed the entire scan of each sequence, it can start again from the beginning. The time elapsed to complete all of the planned scanning sequences is called the revisit time R.

In the most general embodiment, the prescribed pointing positions Pᵢ of each sequence are disposed in any order, but to optimize the revisit time R, it is advantageous to define an order such that the curve B(t) presents the developed angle α as short as possible, that is to say B(t) is the shortest path connecting the pointing positions Pᵢ. If the sequence has pointing positions of different periods of revolution, the optimal solution will be very different in each sequence because the orbital positions will have evolved independently.

Also, in one preferred embodiment, the pointing positions of a sequence are chosen to all present the same orbital period, which guarantees that their relative distances will evolve little from one scan to another, and then makes it possible to define quasi-optimal sequences once and for all.

In one particular embodiment, quasi-circular orbits that is to say orbits with almost zero eccentricity, which concerns the vast majority of satellites, are scanned. The best-known circular orbit is the geostationary orbit. In this case, the orbital positions are on the equatorial plane and fixed for a fixed observer on the surface of the globe. The largest possible arc portion α is the measurement of the geostationary arc from its Eastern end to its Western end at the minimum elevation El₀. If the sequence scans only the geostationary arc, the revisit time R as defined above is the time elapsed between two consecutive measurements of the same pointing or orbital position. For scanning a LEO orbit, the revisit time separates measurements which can be made at different anomalies because this revisit time is not necessarily a whole number of periods of revolution of the considered orbit.

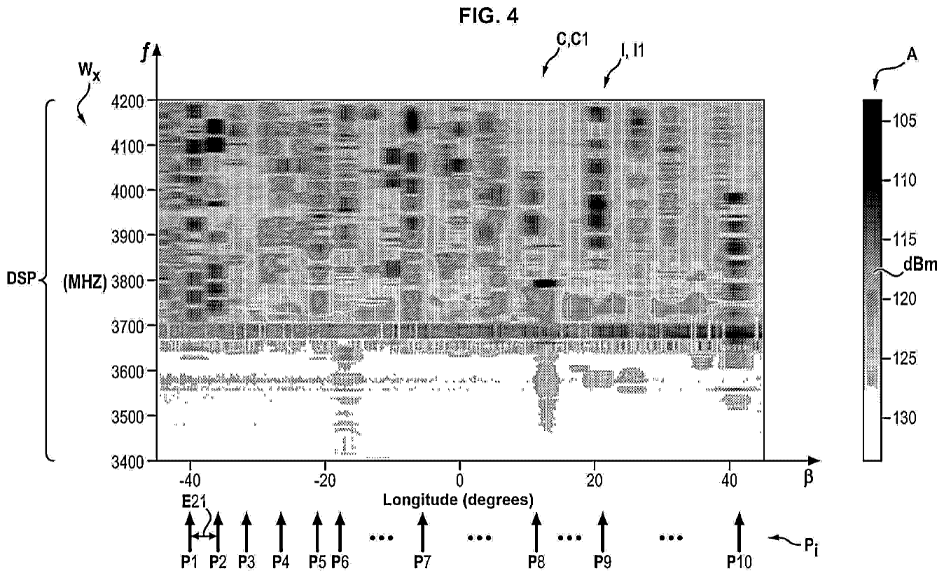

FIG. 4 and following were carried out considering a scan of the geostationary arc. In this case, the scanned pointing position element is the longitude which corresponds to the anomaly on the geostationary arc unequivocally. In the more general case of a scan of any orbit, the longitude should be replaced by the anomaly without this modifying the scope of the figures.

Another special case consists in scanning the positions of a constellation of satellites. In general, a satellite constellation consists of a small number of periods of revolution (1 for GPS, Galileo, O3B, OneWeb, Iridium Next; 3 for the Kuiper project and the phase 2 of Starlink; 4 for the phase 1 of Starlink). At each of these periods Pᵣ (corresponding to an altitude), the satellite constellation places a large number of satellites in circular orbits and on a series of orbital planes, all at the same inclination and evenly spaced, that is to say their ascending nodes are multiples of 360/p° with p distinct orbital planes. Here, the planned scan can consist in varying both the anomaly and the ascending node. For example, when the constellation is strongly inclined, it can be sought to scan the orbital positions corresponding to the location of each orbit which is closest to the polar axis, while traversing the successive planes, that is to say by varying the ascending node step by step in the increasing or decreasing direction. The scan obtained will form a circle about the polar axis and it has a small angular displacement to traverse the considered altitude of the constellation. When the position of the antenna is sufficiently close to the pole, then the axis of sight 21 of this scan always has a significant elevation and the sequence can be maintained indefinitely.

### Step E2: Collection, Acquisition and Recording of the Signal

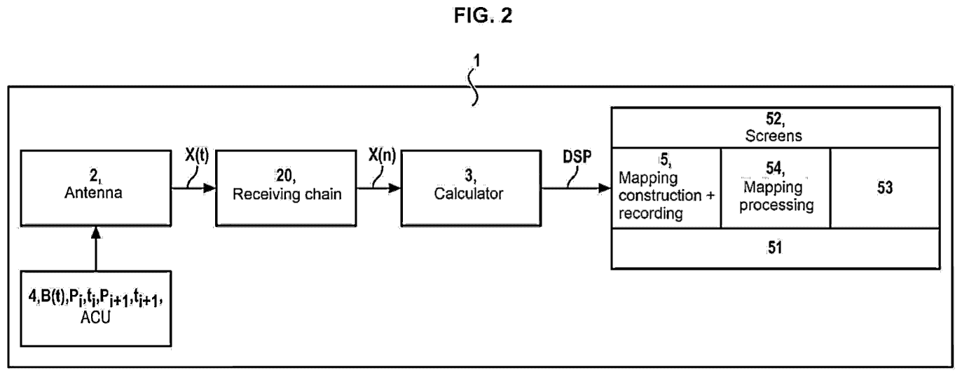

In FIG. 2, the recording device 1 according to the invention comprises one (or several) receiving antenna(s) 2 pointed along an axis of sight 21. The antenna 2 directed above El₀, collects a radiofrequency signal X(t) which is a function of time.

The device 1 comprises a chain 20 for radiofrequency receiving and digitally converting the radiofrequency signal X(t), wherein the chain acquires the radiofrequency signal X(t) in the form of digital samples X(n).

An example of receiving chain 20 downstream of the antenna 2 in a station is described below with reference to FIG. 2. The station incorporates a radiofrequency chain 20 between the antenna 2 and the calculator 3. In step E2, the radiofrequency signal X(t) output from the antenna 2 is digitized at the end of the radiofrequency receiving chain 20. Conventionally, this receiving chain 20 comprises a microwave filter which selects the useful band, a low noise amplifier (LNA) which lowers the frequency and which strengthens the signal to sufficient power, followed by a down converter brings the band of interest in an intermediate band where the signal is finally sampled and digitized by an analog to digital converter (ADC) working at the sampling frequency fₑ. A sequence X(n) of samples at index n, acquired at the instants n/fₑ is thus obtained. As an alternative to this single-channel diagram represented in FIG. 2, the preamplified signal can also be divided into several channels of index x on which sub-bands Wₓ are processed, each having its acquisition chain. There is then a frequency converter then a digitizer on each channel, which makes it possible to increase the processed instantaneous band. There can be otherwise only one digitizer and alternately a switching of each sub-band Wₓ on its input, but this less expensive architecture increases in return the time necessary to carry out an acquisition.

The digitized signal X(n) is then recorded. The recording of the raw signal can be kept if needed, for the desired time, depending on the memory capacity 51.

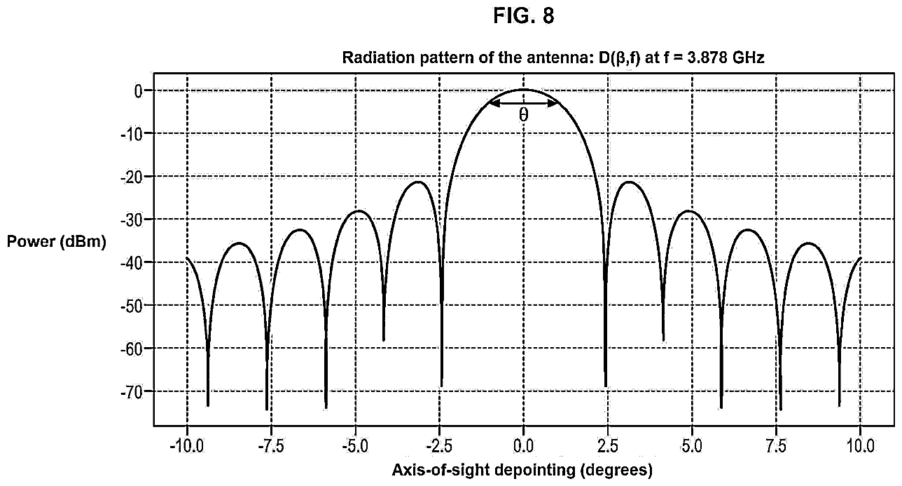

In practice, the antenna 2 can generally be in the shape of a parabolic reflector 22, whose external edge 23 delimits an opening diameter 24. Of course, the antenna could be in the form of a reflector with a shape other than parabolic. The antenna 2 is not a perfect antenna with an infinitely fine beam. Also, it does not only collect the signal derived from its axis of sight 21 but a multitude of contributions coming from various directions which are weighted according to its radiation pattern at the considered frequency. The radiation pattern at the frequency f, an example of which is given in FIG. 8, presents a main lobe, of width θ, which concentrates the greatest power contribution about the axis of the antenna aligned with the axis of sight 21. The side lobes collect the signal more weakly coming from directions further away from the axis of sight 21. For a satellite S emitting an EIRP (equivalent isotropically radiated power) Pe from the direction of angle γ, determined by its azimuth and its elevation, the power received by the antenna pointed at an axis of sight β, also determined by its azimuth and its elevation, is Pr=Pl·Pe·D (γ·β,f), where Pl is the free space loss which is (λ/4πd)² with λ the wavelength and d the distance from the satellite. Here, the angle subtraction should be understood in the sense of the composition of rotation, −β representing the rotation opposite to the one that allowed pointing the axis of sight β.

The pattern D(γ, f) is a function of the frequency and of the depointing angle γ (which is the angular deviation with respect to the axis of sight 21, as represented by way of example in FIG. 8) which provides the power gain of the antenna. This is maximum for zero depointing. In principle, the antenna, which can for example be of parabolic shape, is of symmetry of revolution. The main lobe is therefore also of symmetry of revolution and its width θ does not depend on the orientation of the depointing. The width θ of the main lobe at 3 dB, or otherwise at y dB with y different from 3 is defined. The width of the lobe is twice the admissible depointing so that the gain loses y dB. For y being 3 dB, this corresponds to a loss of half of the maximum gain in the axis of sight 21.

In one embodiment, the prescribed successive pointing positions are isolated positions of interest. In another preferred embodiment, the objective of the scan is to collect in the process the signal derived from all the intermediate positions between two successive pointing positions prescribed in the sequence so as to detect active satellites that could be located there. For this to be met, these positions must be collected in the main lobe of the previous pointing position or of the next pointing position, as desired. More specifically, it is required that each intermediate position is located in the cone of lobe width θ around the previous or next pointing position, so as to guarantee a certain quality of collection of the signal which may come therefrom. Consequently, in this preferred embodiment of the invention, two successive pointing positions at which the spectral density is measured must correspond to tracking trajectories deviated by a value of axis of sight 21 less than the width θ of the main lobe, this in the time interval where we switch from one to the other. This condition is reflected by the inequality:

|β(P_{i,+1},tᵢ)−β(Pᵢ,tᵢ)|<θ_{ydB}et/ou|β(P_{i,+1},tᵢ₊₁)−β(Pᵢ,tᵢ₊₁)|<θ_{ydB}

When y is chosen equal to 1 or 2 dB, the considered antenna lobe is narrow and the signal collected at each intermediate pointing position is little distorted. On the other hand, with y equal to 3 or 4 dB, the antenna lobe is wider at the cost of greater distortion of the signal collected at the intermediate pointing positions.

### Step E3: Recording of Power Spectral Density

During step E3, the recording device 1 comprises a calculator 3 able to calculate, from the samples X(n) of the digitized signal taken in a window around a date t (in the following the terms date t and instant are synonymous), a raw power spectral density DSb(Pₛ,t,f) at the frequency f in one (or several) of the frequency sub-bands Wₓ and for each pointing position traversing the sequence of prescribed successive pointing positions Pᵢ(tᵢ) on the dates t=ti. The calculator 3 and the number of central processing units (CPU) thereof are adapted as needed in computing power. The calculator 3 can be implemented by one (or several) processor(s), and/or one (or several) microprocessor(s), and/or one (or several) central processing unit(s), and/or one (or several) computer(s), and/or the like.

The device comprising the down-converter, the sampler of the radiofrequency chain 20 and the calculator 3 allows, for each sub-band Wₓ, doing the work of a spectrum analyzer. The advantages of the architecture in FIG. 2 compared to a spectrum analyzer are a capacity for exhaustive recording of the acquisitions and of the power spectral density, and a faster execution. Indeed, any dead time between the windows used to calculate the power spectral density can be avoided. The same processing operations made with a spectrum analyzer would therefore result in a longer revisit time R.

The radiofrequency activity is revealed by the presence of spectral components of the collected signal which are higher than the background noise level. The radiofrequency activity recording therefore consists in measuring the power spectral density of the signal at each prescribed pointing position. To do so, a duration window F of the signal has to be chosen, its Fourier transform has to be calculated then its module has to be squared and the whole has to be divided by the duration of the window. This provides a raw estimate of the power spectral density which has a frequency resolution of 1/F and a significant noise-related level fluctuation. To limit this effect, the power spectral density can be averaged, using two possible methods. The first one consists in averaging q adjacent frequencies, the second one consists in averaging q consecutive measurements, therefore processing a signal duration D=qF. On an analog spectrum analyzer, this is called respectively video filtering or averaging. In both cases, the effective resolution is reduced by a factor q compared to what a raw Fourier transform allows over the same signal acquisition duration D. A frequency resolution df with an averaging of depth q therefore require an acquisition duration also called exposure time D=q/df.

According to one embodiment of the invention, the calculator 3 starts by cutting the digitized signal X(n) into windows of duration Dᵢ fixed respectively on each position Pᵢ, comprising a number Mᵢ of samples and therefore of duration Dᵢ=Mᵢ/fₑ. Typically, if the scan is discrete, the window Dᵢ begins at the instant tᵢ and stops before the ACU tracks the next pointing position, therefore before tᵢ₊₁. If the scan is regular, then the window Dᵢ will be preferably centered on the instant tᵢ. The spectral density calculated in step i therefore corresponds to a collection of the radiofrequency signal X(t) centered at the pointing position Pᵢ. Each raw spectral density measurement, that is to say before any reprocessing, is therefore both a function of the frequency f in the sub-band Wₓ and of the succession of pointing positions Pᵢ. It was seen in the description of step E2 that the antenna 2 collects the signals coming from the cone of width θ around the axis of sight. This therefore means that θ constitutes the spatial resolution of the spectral density measurements.

Between the instants tᵢ and tᵢ₊₁, the average pointing speed is defined as the angle of sight variation divided by the time interval. This is broken down into a relative scanning speed and a tracking speed according to the following formula:

[β(Pᵢ₊₁,tᵢ₊₁)−β(Pᵢ,tᵢ)]/(tᵢ₊₁−tᵢ)=Vₚ(tᵢ₊₁)=[β(P_{i,+1},tᵢ₊₁)]−[β(Pᵢ,tᵢ₊₁)]/(tᵢ₊₁−tᵢ)+[β(Pᵢ,tᵢ₊₁)−β(Pᵢ,tᵢ)]/(tᵢ₊₁−tᵢ)=Vₛ(tᵢ₊₁)+Vₜ(tᵢ₊₁).

The choice of a minimum acquisition duration D to guarantee a quality of measured spectral density, that is to say its frequency resolution and the noise fluctuation, requires that the pointing positions follow each other at instants spaced by at least the exposure time: tᵢ₊₁−tᵢ>Dᵢ>D. Consequently, in the preferred embodiment where the axes of sight of the successive pointing positions are smaller than the lobe width θ, the relative scanning speed Vₛ which is the difference between the average pointing speed Vₚ and the tracking speed Vₜ of the current pointing position must remain less than θ/D.

The maximum scanning speed is determined by the exposure time and the side lobe width. This scanning speed is by definition zero if a pointing position is just tracked. The decomposition of the pointing speed into tracking and scanning speed applies to apparent speeds which are an average, regardless of the scanning mode. This is valid whether it is performed in a discreet mode or in a regular mode. In the particular case of scan of the Clarke belt, the tracking speed is zero because the orbital positions are fixed from the geographical position O of the station, therefore the pointing speed is equal to the scanning speed and therefore must remain less than θ/D.

The tracking speed is required by the celestial dynamics of the chosen orbital positions. It strongly depends on the period of revolution of the orbital positions within a scan. For its part, the scanning speed is limited by θ/D. When the expected quality of the power spectral density measurement, therefore the exposure time D have been chosen, the scanning speed is therefore proportional to the lobe width θ. Maximizing the lobe width therefore makes it possible to maximize the scanning speed, and therefore the pointing speed, and consequently minimize the revisit time R, whatever the sequences of pointing positions planned in step E0.

Based on this observation, the invention proposes, in one preferred embodiment, that the maximum opening diameter 24 of the antenna 2 is less than or equal to 6 meters. For example, the maximum opening diameter can be greater than or equal to 1 meter and less than or equal to 6 meters.

The antenna 2 can have a maximum opening diameter 24, which is less than or equal to 4 meters, being able to be provided at least for the receiving frequency sub-band Wₓ=Ku or other. For example, the maximum opening diameter of the antenna 2 can be greater than or equal to 1 meter and less than or equal to 4 meters, the antenna can be provided at least for the receiving frequency sub-band Wₓ=Ku or other.

The antenna 2 can have a maximum opening diameter 24, which is less than or equal to 6 meters, being able to be provided at least for the receiving frequency sub-band Wₓ=C or other. For example, the maximum opening diameter of the antenna 2 can be greater than or equal to 1.5 meters and less than or equal to 6 meters, the antenna can be provided at least for the receiving frequency sub-band Wₓ=C or other.

Thus, the invention provides an antenna size large enough to identify with certainty a signal at the minimum density threshold of EIRP (equivalent isotropically radiated power) of the objects sought. The antenna 2 is chosen to be of just sufficient size to be able to detect the signal from a satellite emitting at the equivalent isotropically radiated power threshold to be read.

For example, the antenna 2 can have a maximum opening diameter 24, which is less than or equal to 2.50 meters (2 meters and 50 centimeters), and can be provided for the receiving frequency sub-band Wₓ=Ku and/or C or others. For example, the maximum opening diameter 24 can be greater than or equal to 1.50 meters (1 meter and 50 centimeters) and less than or equal to 2.50 meters, being able to be provided for the receiving frequency sub-bands Wₓ=Ku and/or C or others.

For example, the antenna 2 can have a maximum opening diameter 24, which is less than or equal to 2.10 meters (2 meters and 10 centimeters), being able to be provided for the receiving frequency sub-bands Wₓ=Ku and/or C or others. For example, the maximum opening diameter 24 may be greater than or equal to 1.90 meters (1 meter and 90 centimeters) and less than or equal to 2.10 meters, being able to be provided for the receiving frequency sub-bands Wₓ=Ku and/or C or others. In the receiving frequency sub-bands Wₓ=Ku and/or C or others, this makes it possible to take an antenna 2, for example of the order of 2 meters in diameter. These choices allow the shortest possible revisit time R.

The maximum opening diameter 24 of the antenna 2, described above, is particularly advantageous in combination with the recording of refined power spectral densities DSa, calculated during step E6 described below, because it is this combination that makes it possible to detect a larger number of satellites with a shorter revisit time and a lower cost.

### Step E4: Construction of the Mapping

The mapping C is organized by pointing position Pᵢ and comprises the power spectral density DSP for one or several pointing positions Pᵢ. For each, it was possible to record the power spectral density DSP as a function of the frequencies f with a measurement made on the date t, since it corresponds to one of the successively prescribed pointing positions Pᵢ for i ranging from 1 to N, for each recording sequence. The frequency f is a frequency in one of the receiving frequency sub-bands Wₓ. The recording can be sent directly for visualisation or for use by another system, but in the preferred embodiment, the mapping C is recorded.

To do so, according to one embodiment, the recording device 1 comprises a recording device 5 for recording a mapping C of the read power spectral densities DSP(Pₛ,f,t) having been measured by the antenna 2 to the date t while it was pointed at the pointing position Pᵢ. The recording device 5 can comprise one or several permanent memories 51 or others to record the mapping C and/or one or several display screens 52 to display an image I of the mapping C and/or one or several physical outputs 53 to provide the mapping C or an image I thereof, and/or one or several modules 54 for processing the mapping C.

In one embodiment, the read power spectral density DSP(Pₛ,f,t) is chosen directly equal to the raw power spectral density DSb(Pₛ,t,f) calculated in step E3. In another embodiment, which will be described below in step E6, the read power spectral density DSP(Pₛ,t,f) is calculated by the calculator 3 with a reprocessing that refines the raw power spectral density DSb(Pₛ,t,f).

For each pointing position Pᵢ of the mapping C, it is possible to keep the last spectral density recording DSP or keep any depth history, depending on the need and on the available memory capacity 51. The organization of the storage in memory 51 of the mapped pointing positions Pᵢ is a priori independent of the succession of the prescribed orbital positions Pᵢ. When the system has a multitude of antennas 2, the mappings established by each one are grouped together, knowing that in step E0, each one is preferably planned to track different orbits or portions of orbits, or more generally sequences of separate prescribed pointing positions Pᵢ. Given the main lobe of the antenna, the DSP at the pointing position Pᵢ actually incorporates spectral components collected in the cone of lobe width θ around the axis of sight 21 at the date t. The signal is therefore collected from an area of positions in the vicinity of the prescribed pointing position Pᵢ. The satellites having an orbital period equal to that of the prescribed pointing position Pᵢ remain in the vicinity thereof, but those having a slightly different orbital period PS drift regularly relative thereto. For example, in the particular case where a circular orbit is scanned, the mapping C incorporates satellites of the same plane having close quasi-circular orbits but with the same orbital period and it will be seen that these satellites oscillate in time around the prescribed pointing position Pᵢ which is perfectly circular. A satellite of the same plane having a slightly lower or higher orbital period, although on a perfectly circular orbit, will appear to have an anomaly that increases or decreases in a linear manner.

### Step E5: Visualization, HMI

A mapping C can thus be expressed graphically in easily interpretable images for objects whose relative positions vary little and slowly. The images I constituted to represent the mapping C therefore consist in forming the function of the power spectral density DSP for the last recording, otherwise a previous recording specified by the user, corresponding to a pointing position Pᵢ of the given mapping according to a two-dimensional variable: the frequency and a variation parameter of the pointing position Pᵢ.

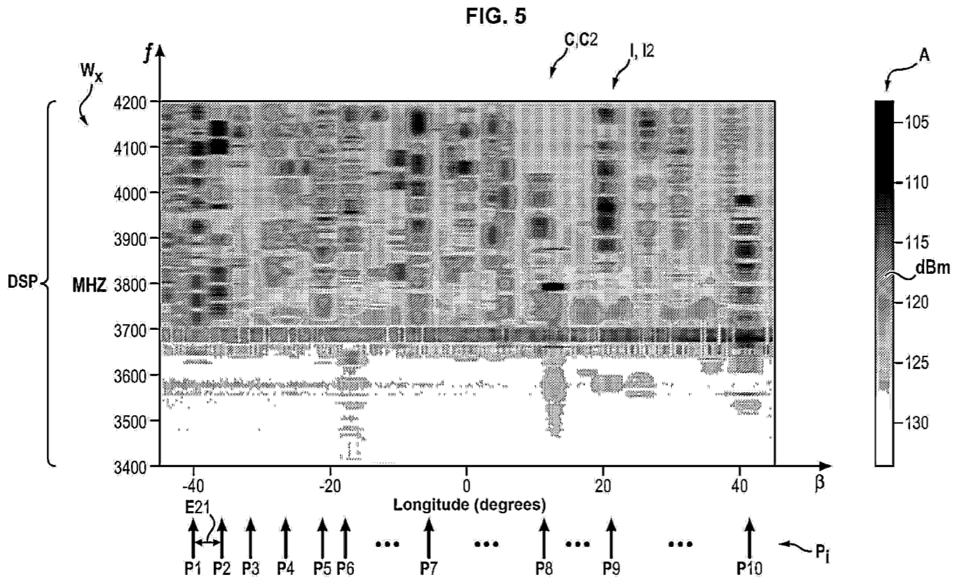

In one embodiment, described below with reference to FIGS. 4 and 5, the image I of the mapping C represents on the abscissa the successively prescribed pointing positions Pᵢ of a recording, which are thus disposed side by side in the chronological order of each recording, and on the ordinate the frequency f. It is possible to reverse the axes with the pointing positions Pᵢ on the ordinate and the frequencies on the abscissa. In the particular case where the scan of an orbit has been planned by varying the only anomaly, the successive pointing positions Pᵢ correspond to increasing or decreasing anomalies on this orbit.

In another embodiment, the variation parameter of the pointing position Pᵢ is synthetically reconstituted from a mapping C which contains recordings of power spectral density DSP for a multitude of orbits at the same orbital period. For example, for a constellation as seen above, the pointing positions Pᵢ have anomalies and variable ascending nodes, it is then possible to reconstitute an image I whose variation parameter of the pointing position Pᵢ is the ascending node, even though the prescribed sequences Pᵢ have been acquired in a different order, in particular by scanning each orbit.

The pixel value on each ordinate and on each abscissa of the image I represents the level A of the read power spectral density DSP, measured at the frequency f during a scan B(t). The spectral densities DSP are therefore disposed vertically in the image I, with a spectrum per abscissa of the image I. The level A of each read power spectral density DSP is represented by a color, typically according to a decreasing wavelength from blue to red, or a brightness level or a gray level, which varies unequivocally depending on the level A, for example in a monotonous, increasing or decreasing manner. For example, the level A is expressed in dBm in FIGS. 4 and 5.

As an alternative to an image where the pixel value represents the DSP function, it is also possible to make a projection of the surface of the curve of level A, function of the frequency and of the pointing position Pᵢ. In this case, the level A is represented along a third side axis perpendicular to the abscissa and ordinate axes, which provides a three-dimensional surface which is then projected into two dimensions. It is possible to make an isometric projection of the surface in a grid, according to a succession of section lines disposed with an offset. It is also possible to constitute an image by visualizing the cutting planes that are moved forward or backward, but it is not possible to represent everything in a single image. Other image constitution techniques exist in the state of the art and are applicable.

The high values of Level A, well above the background sky noise level, reveal the presence of active satellites. The formation of the images I therefore constitutes a preferred embodiment to represent the mapping, because it makes it possible to easily visualize the use of the radiofrequency spectrum by the artificial celestial objects. Typically, when the constitution of the image is a very rapid process, it is not necessary to record the result, but in the preferred embodiments, a history of the last displayed images I is recorded.

### Step E6: Optional Processing Operations of the Mapping

The exploitation and the processing of the mappings with the aim of identifying satellites can be done by a human operator, but can also be largely automated. These optional processing operations of the raw mapping DSb can be performed by one or several mapping processing modules 54 in FIG. 2, or otherwise by the same calculator 3. Among these processing operations, it is possible to perform: a comparison with the declarations of operators of the positions and frequency plans, a differential processing between successive mappings (see below) to identify the changes.

A sending to the tracking system can be provided to refine the precise orbital position of each spectrum portion and thus separate the co-located objects, that is to say whose orbital positions are close enough to be captured in the main lobe of a single spectrum measurement.

Successive mappings and differential processing In one embodiment, called consecutive mapping embodiment and described below with reference to FIGS. 1 to 6, the antenna 2, the calculator 3, the drive device 4 and the recording device 5 are able to record histories C1, C2 (or more) of the mapping then to deduce several images I1, I2 for two scans of the same sequences of prescribed pointing positions Pᵢ(tᵢ). The image I2 extracted from the mapping C2 is made in an acquisition time interval, which is subsequent, for example of several hours or a few days as represented in FIGS. 4 and 5, compared to the acquisition time interval of the image I1 extracted from the mapping C1. In principle, when all of the scanning sequences were visible above the minimum elevation from the geographical position O of the station, the consecutive acquisitions are by definition spaced by the revisit time R. The accumulation of acquisitions derived from consecutive cycles at the same position allows averaging the effects of noise beyond the averaging depth.

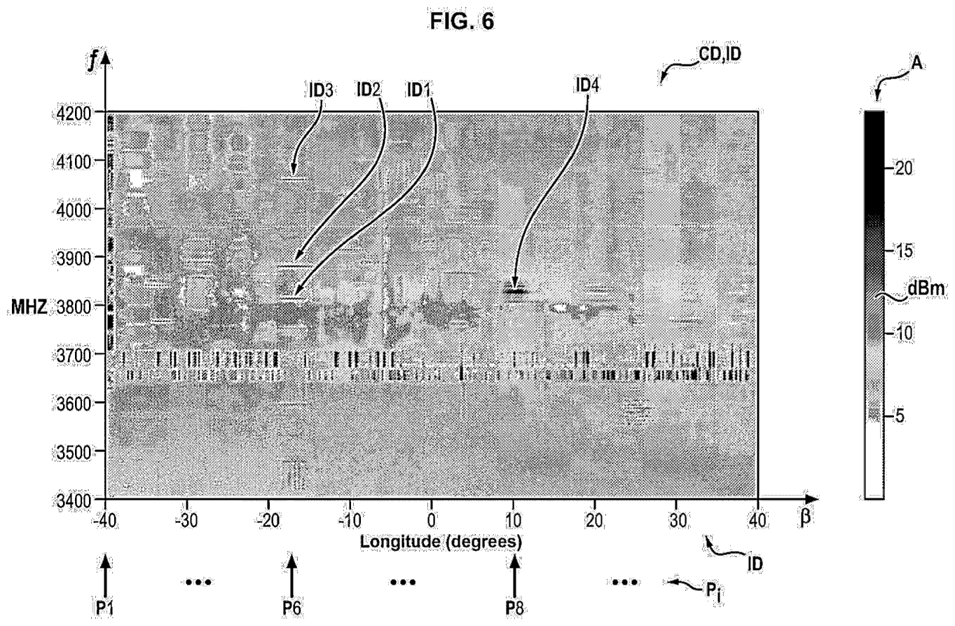

According to an improvement of this embodiment, called differential mapping improvement embodiment, described below with reference to FIG. 6, the antenna 2, the calculator 3, the drive device 4 are able to calculate at least one differential mapping CD between two distinct historical records C1, C2 of the mapping, at the same prescribed pointing positions Pᵢ. A differential image ID represented in FIG. 6 and equal to the image I2 in FIG. 5, from which the image I1 in FIG. 4 is subtracted by subtraction of the power levels A, that is to say the pixel values from each other, for identical abscissas and identical ordinates, that is to say at the identical frequencies and identical pointing positions Pᵢ is deduced. This differential processing of the consecutive mappings C1, C2 makes it possible to detect with certainty the spectrum use change events of longer duration than the revisit time R (station acquisition or decommissioning, change of frequency plan, of position, etc. . . . ). For example, the image I1 in FIG. 4 was made on Apr. 1, 2021, and the image I2 in FIG. 5 was made on Apr. 5, 2021. The differential image ID in FIG. 6 shows three appearances and disappearances ID1, ID2, ID3 of lines in the power spectral density DSP of satellites located in position P6, whose frequencies f can be determined, and an appearance and disappearance ID4 of a spectral line of a satellite located in position P8, whose frequency f can be determined.

### Peak Discrimination and Approximation with the Declarations of Operators

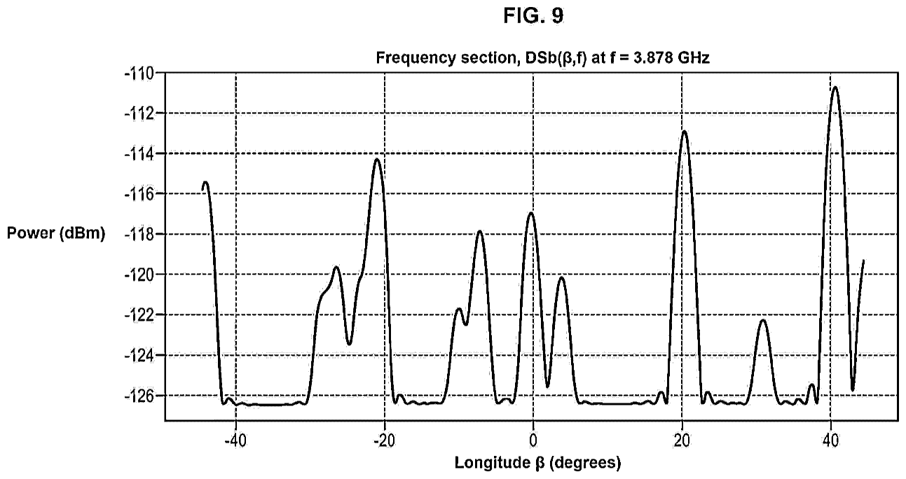

In one embodiment, the calculator 3 and the recording device 5 are configured to discriminate the spatial lines of the power spectral density DSP by peak detection, that is to say local maximum detection, algorithms. The peaks with their A-level can be used to summarize the content of the longitudinal curve of level A of power spectral density, which is illustrated in FIG. 9.

The peaks at a frequency f are the best estimation of the position of a satellite emitting a signal at that frequency f. It is possible to attempt to approximate these results with the declarations provided by the operators in order to name the satellites discovered and indicate those that are not declared.

### Inverse Convolution

In one embodiment, called spectral density recombination embodiment, the calculator 3 and the recording device 5 are able to reprocess the mapping by transforming the raw power spectral density DSb(Pᵢ,tᵢ,f) into a refined power spectral density DSa by application of an inverse convolution processing aimed at reducing the effect induced by the radiation pattern of the antenna 2. Several methods are possible for this purpose. Thus, in a non-limiting implementation described below, the calculator 3 will proceed by linear combination of several successive raw power spectral densities DSb(Pᵢ,tᵢ,f). Thus, the refined power spectral density DSA or DSa(Pᵢ,tᵢ,f) is a linear combination of the raw power spectral densities DSb(Pᵢ₊ₖ,tᵢ₊ₖ,f) taken at the pointing positions Pᵢ of the instants tᵢ₊ₖ, where k takes the values ranging from −m to +m.

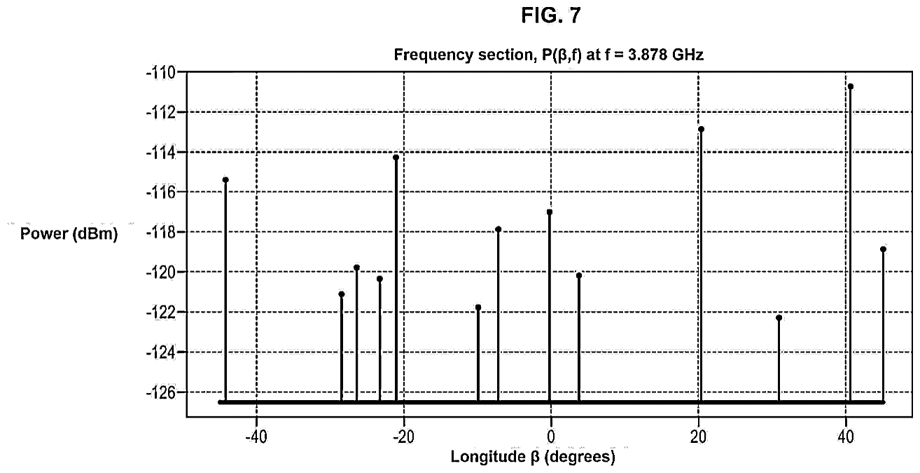

It was seen in step E2 that the antenna pointed at an axis 21 of sight β collects the signal from a satellite S emitting from the direction of angle γ according to a received power proportional to Pe·D(γ·β,f), where Pe is the EIRP of the satellite and D is the pattern of the antenna 2 of the station. According to this formula, the antenna pattern has the effect of spreading the contribution of the satellite over the width of the main lobe θ and creating responses that are artifacts at the positions of the side lobes. When it comes to a group of satellites Sⱼ of EIRP being Pⱼ for j varying from 1 to P, a power is received which is the sum of the contributions of each satellite Sⱼ, i.e. DSb(β,f)=ΣPⱼ·D(γⱼ·β,f). In the mathematical sense of the distributions, it is possible to represent the spectrum of the signal derived from the sky at a frequency f as a series of Dirac lines, positioned at the axes of sight γⱼ and whose amplitude is the EIRP Pⱼ. The distribution P=ΣPⱼ·δ(γ·γⱼ), where δ is the Kronecker symbol designating a Dirac at position 0, illustrated in FIG. 7, is the perfect mapping sought to be measured, the one that an antenna with an infinitely thin main lobe and infinitely low side lobes would obtain. FIG. 7 represents an example of such a distribution P(B,f) composed of Diracs representing the satellites observed by the antenna 2 which scans the geostationary arc, at the angular positions β=γⱼ (expressed in equivalent longitude) on the abscissa and the power in dBm on the ordinate. The power received by the antenna 2 at the frequency f is then proportional to the integral:

∫ΣPⱼδ(γ−γⱼ)D(γ−β)dγ=ΣPⱼD(γⱼ−β)

where δⱼ(γ) is the Dirac impulse at the axis of sight γⱼ. Formally, the integral calculates a convolution at the position β of the ideal mapping formed by Dirac lines with an impulse response which is the radiation pattern of the antenna 2, flipped by 180°. FIG. 8 represents an example of radiation pattern D(β,f) of the antenna 2, for f=3.878 GHz, with a gain expressed in dBi on the ordinate as a function of the deviation of the angle B with respect to the axis of sight 21 on the abscissa, this deviation being called axis-of-sight depointing in FIG. 8. FIG. 9 represents an example of power spectral density DSb(β,f) received by the antenna 2 which scans the geostationary arc, at the frequency f=3.878 GHZ, with the power expressed in dBm on the ordinate as a function of the axis of sight β (expressed in equivalent longitude) on the abscissa. It illustrates the effect of the convolution by the pattern in FIG. 8 on the power curve received as a function of the angle of sight β, to be compared with the power curve emitted in FIG. 7. The effect of the convolution is also perfectly visible in FIGS. 4 and 5 where it is seen that each satellite is distinguished by a 4° wide spot counting several levels of gray attenuating at the edges and corresponding to each side lobe of the antenna 2.

The convolution of the equation above applies with an integration variable which is the angle of sight of the satellites and not the pointing position Pᵢ. When all the satellites collected during the scan can be considered as being on the scanning curve B(t), then the convolution which is natively two-dimensional just like the angles of sight, can be compared to a one-dimensional convolution, performed along the scanning curve B(t). This is considered to be true in the case of scan of a single orbit, by varying the only anomaly, when the satellites collected in the considered sub-bands Wₓ are necessarily on this same orbit because they obey the international regulations of the ITU preventing the interference. In this case, the impulse response of another one-dimensional convolution, called inverse convolution is determined, which in a way makes it possible to neutralize the effects of the convolution by the antenna pattern, that is to say the combination of the two convolutions approximates the convolution by a Dirac and presents a finer main lobe as well as significantly reduced side lobes.

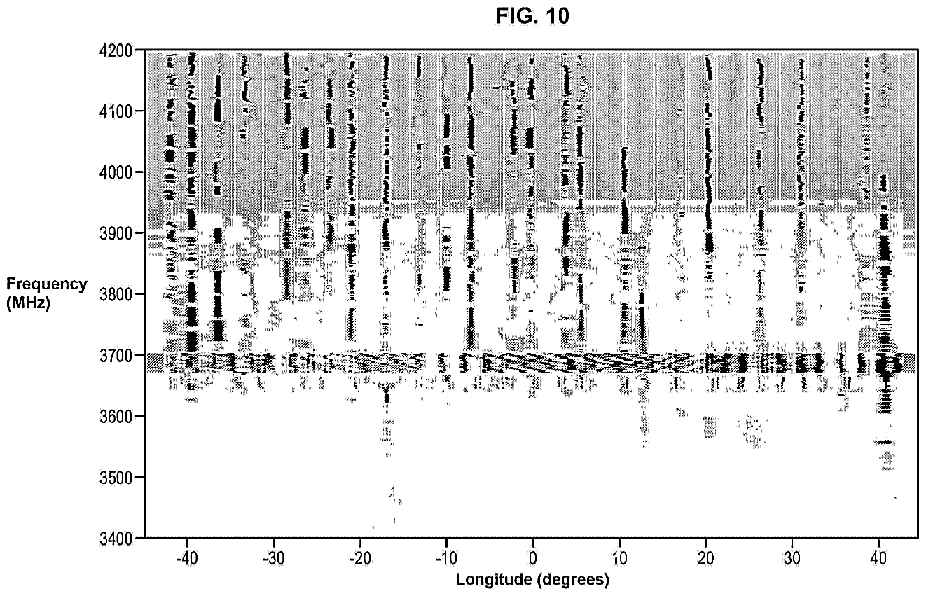

When the scanned orbit is the geostationary arc (Clarke belt), the angle of sight γ of a pointing position Pᵢ is fixed, there is therefore a one-to-one relationship between the two. The instant t at which the antenna 2 made the collection at the axis of sight β does not matter. The impulses D(γ·β) as a function of the variable γ translate when the angle of sight β of the antenna varies but deform very little. The inverse convolution therefore gives excellent results as shown in FIG. 10. When the scanned orbit is other than the Clarke belt, it moves in the sky as a function of the rotation of the earth and the pointing positions Pᵢ move along the orbit as a function of the period of revolution Pᵣ. Before proceeding with the inverse convolution, it is therefore appropriate to replace the measurements of DSb made at the angle of sight β(Pₛ,t) at the angle of sight that the corresponding pointing position Pᵢ presents at a single reference date to, that is to say β(Pₛ,t₀). This correction however introduces some distortions with respect to a recording that would be the perfect result of an instantaneous one-dimensional convolution between the distribution of the satellites and the antenna pattern, along the scanning curve β(t). The inverse convolution will be all the more efficient as a high orbit is scanned, therefore with a low period Pᵣ.

In one embodiment called inverse spatial convolution embodiment, which is a sub-mode of the recombination of spectral densities, described below with reference to FIGS. 3 and 7 to 10, the calculator 3 is able to calculate during the step E6 the refined power spectral density DSa(β,f) by inverse convolution of the raw power spectral density DSb(β,f) of the signal picked up by the antenna 2 at a frequency f in a sub-band Wₓ, the inverse convolution taking place according to the angle-of-sight β variable. The impulse response of the inverse convolution is calculated from the radiation pattern D(β,f) of the antenna 2 which was measured beforehand at the same frequency f and was tabulated in the memory 51 of the calculator 3, during the step E0 of the method.

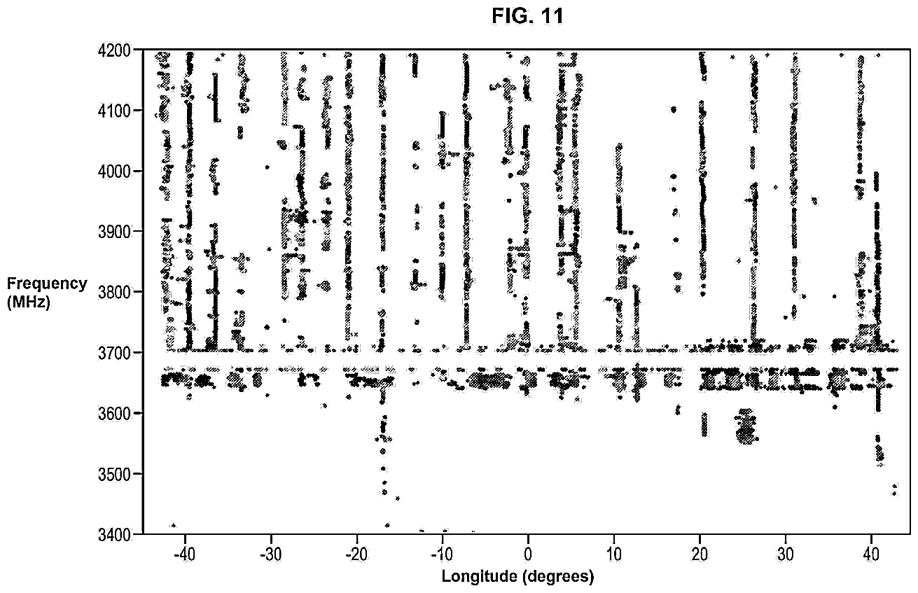

In practice, the improvement of the response by this inverse convolution operation is significant, with side lobe artifacts which disappear and a main lobe whose width is almost reduced by half. It is seen in FIG. 10 that the artifacts which spread the response of an orbital position over 4° in FIGS. 4 and 5 have clearly decreased and are less than 1°. The power of spatial discrimination is thus improved by correcting defects introduced by the radiation pattern of the antenna. This significantly reduces the false alarm rate and the object non-detection rate. Applying the search for peaks to the refined power spectral density DSa rather than to the raw power spectral density DSb makes it possible to substantially improve its contribution. This result is illustrated in FIG. 11 where are indicated by points, satellites whose detected position is on the abscissa and which emit a signal at the frequencies indicated on the ordinate. The small deviations in longitude on the geo arc allow affirming that it is certainly different but co-located satellites, which was impossible to detect in FIG. 4 or 5.

### Step E7 (Optional): Tracking

The mapping C can be reprocessed by tracking, which makes it possible to improve the spatial resolution. Thanks to the calculation of correlation of the signals picked up by antennas remote from each other, the orbital tracking system allows a very accurate resolution of the orbits, which approximates the resolution of perfect Diracs since accuracies of the order of 150 meters at the geostationary arc are possible.

Once the spectral lines have been identified in the mapping C by the device 1 according to the invention, the individual characteristics of these spectral lines can be transmitted to the known orbital tracking system which will be able to perform new remote acquisitions, thus making it possible to separate all the celestial objects by processing operations based on the correlation. It then possible to individually track these celestial objects using techniques requiring more computing power or acquisition duration, in particular by the correlation of remote acquisitions used in the known orbital tracking system. The spatial separation of the objects detected at a pointing position Pᵢ by the device according to the invention can thus be performed by the orbital tracking system. The technique of determining orbits by the orbital tracking system can be used to separate the objects detected at a given pointing position Pᵢ by an acquisition at this pointing position Pᵢ alone, which minimizes the duration of the orbit determination process. The known orbital tracking system will perform the correlation of remote acquisitions made at the tracked orbital positions alone.

The orbital tracking system and the radiofrequency activity recording device according to the invention can use identical antennas 2, or share the same antenna farm. Indeed, the constraint of a sufficient signal-to-noise ratio to detect the signal derived from the satellites is the same for these two systems. The mapping established by the system for recording the radiofrequency activity provides a spatial resolution which, once refined by one or several methods of step E6, makes it possible to locate the emission in a cone of width smaller than the main lobe width of the antenna. The tracking is therefore immediate, the orbital tracking system simply collecting this pointing position Pᵢ alone from its remote sites, without having to perform any scan, unlike the radiofrequency activity recording system. The acquisition by the tracking system is therefore optimized in time. Finally, the mapping advantageously replaces the use of operator declarations.

The combination of the two systems argues for the choice, according to one embodiment of the invention of small antennas 2. The device is then cheaper, faster and ultimately more accurate than a single antenna thanks to the reprocessing by the orbital tracking system.

Of course, the embodiments, characteristics, possibilities and examples described above can be combined with each other or selected independently of each other.

The invention thus allows space monitoring by observation of the use of the radiofrequency spectrum and makes it possible to map the spectral situation in space. The method and the recording device 1 according to the invention allow a detection of any earth-orbiting active emitting object without using extrinsic information from the operators. The invention makes it possible to track the activity of satellites, whether LEO, MEO or geostationary satellites. The invention makes it possible to determine the life cycle of the space objects, that is to say the evolution of their use of the frequency spectrum. In terms of performance of the device, it is possible, if necessary, to improve the spatial resolution (obtained by a sensor composed of a single measuring antenna 2) by application of complementary processing operations, in particular those using the inverse convolution. The orbital positions emitting the signal can be tracked by a system using the same antennas 2 at remote sites. The mapping system described by the invention can substitute the use of the declarations of operators, making both services autonomous without reducing the performance of the known orbital tracking system.

1. A method for recording a radiofrequency activity of at least one artificial satellite, which is earth orbiting and which is emitting a radiofrequency signal, wherein the method comprises the following steps:
pointing, by an antenna control device, at least one antenna to move an axis of sight of the at least one antenna towards at least one sequence of prescribed pointing positions, which are successive and distinct from each other, the at least one antenna being in the form of a reflector, whose external edge delimits a maximum opening diameter, which is less than or equal to 6 meters,
and for each prescribed pointing position:
collecting the radiofrequency signal by the at least one antenna and converting the radiofrequency signal by a radiofrequency chain into a digital signal,
calculating, by a calculator, at least one recording of raw power spectral densities on at least one receiving frequency sub-band from the digital signal,
reprocessing the at least one recording of raw power spectral densities into a recording of refined power spectral densities by applying an inverse convolution processing of a radiation pattern of the at least one antenna in the at least one receiving frequency sub-band by the calculator.

2. The method according to claim 1, wherein the at least one antenna has a maximum opening diameter, which is less than or equal to 4 meters.

3. The method according to claim 1, wherein the at least one antenna has a maximum opening diameter, which is less than or equal to 2.50 meters.

4. The method according to claim 1, wherein the at least one antenna has a maximum opening diameter, which is less than or equal to 2.10 meters.

5. The method according to claim 1, wherein the reprocessing of the at least one recording of raw power spectral densities comprises:
an inverse convolution processing of the radiation pattern of the at least one antenna at a frequency in the at least one receiving frequency sub-band,
a calculation of an impulse response of the inverse convolution from the radiation pattern of the at least one antenna which has been measured beforehand at the same frequency and which has been recorded beforehand in a memory of the calculator.

6. The method according to claim 1, wherein the inverse convolution is performed for a linear combination of several successive raw power spectral densities for the successive prescribed pointing positions.

7. The method according to claim 1, wherein the axes of sight of the prescribed pointing positions, which are successive, are spaced apart by an angle smaller than a width of a main radiation lobe of the at least one antenna, in a time interval where the at least one antenna moves from the prescribed pointing position to the next prescribed pointing position in the at least one sequence.

8. The method according to claim 1, wherein the at least one recording of raw power spectral densities is made by an acquisition of the radiofrequency signal, which is collected by the at least one antenna and which is digitized by the radiofrequency chain according to windows being separate and having a duration being predefined and minimum.

9. The method according to claim 8, wherein to measure the at least one recording of raw power spectral densities at each prescribed pointing position, the calculator for each window of the digital signal calculates a Fourier transform then squares its module and divides the whole by the duration of the window.

10. The method according to claim 8, wherein an average scanning speed of the at least one antenna relative to a tracking speed of the pointing position in the at least one sequence is less than θ/D, where θ is a width of the main radiation lobe of the at least one antenna.

11. The method according to claim 1, comprising a calculation, by the calculator, and a recording, by the calculator, of a mapping constituted by the recordings of refined power spectral densities as a function of a frequency and of the prescribed pointing position.

12. The method according to claim 11, wherein an image is extracted from the mapping by the calculator, wherein the image arranges side by side levels of the refined power spectral densities, read successively at the prescribed pointing positions, in the at least one receiving frequency sub-band, wherein the pointing orbital position and the frequency constitute, as desired, the abscissa and ordinate axes of the image.

13. The method according to claim 12, wherein the level of each refined power spectral density is represented by a pixel value, in particular a color or a brightness level or a gray level.

14. A device for recording a radiofrequency activity of at least one artificial satellite, which is emitting a radiofrequency signal,
wherein the device comprises:
at least one receiving antenna pointed along an axis of sight and able to collect the radiofrequency signal, the antenna being in the form of a reflector, whose external edge delimits a maximum opening diameter, which is less than or equal to 6 meters,
an antenna control unit to point the axis of sight of the at least one receiving antenna towards at least one sequence of prescribed pointing positions, which are successive and distinct from each other,
a radiofrequency receiving and digital conversion chain, which acquires the radiofrequency signal into a digital signal on at least one receiving frequency sub-band,
a calculator able to calculate, from the digital signal, at least one recording of raw power spectral densities on the receiving frequency sub-band, and to reprocess the at least one recording of raw power spectral densities into a recording of refined power spectral densities by application of an inverse convolution processing of the radiation pattern of the at least one receiving antenna in the at least one receiving frequency sub-band by the calculator.

15. A computer program for the implementation of the method for recording a radiofrequency activity of at least one artificial satellite, comprising code instructions for the execution of the following steps, when the computer program is executed on one or several calculators:
pointing, by an antenna control device, at least one antenna to move an axis of sight of the at least one antenna towards at least one sequence of prescribed pointing positions, which are successive and distinct from each other, the at least one antenna being in the form of a reflector, whose external edge delimits a maximum opening diameter, which is less than or equal to 6 meters,
and for each prescribed pointing position:
collecting the radiofrequency signal by the at least one antenna and converting the radiofrequency signal by a radiofrequency chain into a digital signal,
calculating, by a calculator, at least one recording of raw power spectral densities on at least one receiving frequency sub-band from the digital signal,
reprocessing the at least one recording of raw power spectral densities into a recording of refined power spectral densities by applying an inverse convolution processing of a radiation pattern of the at least one antenna in the at least one receiving frequency sub-band by the calculator.
